(19) United States
(12) Patent Application Publication
(10) Pub. No.: US 2026/0129762 A1
(43) Pub. Date: May 7, 2026

(54) WIRING SUBSTRATE

(71) Applicant: IBIDEN CO., LTD., Gifu (JP)

(72) Inventors: Toshihide MAKINO, Gifu (JP); Nobuhisa KURODA, Gifu (JP)

(73) Assignee: IBIDEN CO., LTD., Gifu (JP)

(21) Appl. No.: 19/357,212

(22) Filed: Oct. 14, 2025

(30) Foreign Application Priority Data
Nov. 6, 2024 (JP) 2024-194548

(51) Int. Cl. H05K 1/18; H05K 1/03; H05K 1/11; H05K 3/00; H05K 3/46

(52) U.S. Cl. CPC H05K 1/185; H05K 1/0373; H05K 1/113; H05K 3/0035; H05K 3/4679; H05K 2201/09481; H05K 2201/09518; H05K 2201/09527; H05K 2201/096; H05K 2201/09618

(57) ABSTRACT

A wiring substrate includes a first resin insulating layer having a cavity, a second resin insulating layer formed on the first insulating layer, a component accommodated in the cavity of the first insulating layer and including an electrode facing the second insulating layer, and a third resin insulating layer formed on the first insulating layer. The second insulating layer closes first-surface-side opening of the cavity in the first insulating layer and is closer to a mounting surface of an electronic component than the third insulating layer, the third insulating layer closes second-surface-side opening of the cavity in the first insulating layer and includes a part filling a gap formed between an inner wall of the cavity and the component in the cavity, and the cavity has a trapezoidal cross-sectional shape having a distance between opposing legs decreasing from the second surface toward the first surface of the first insulating layer.

### CROSS-REFERENCE TO RELATED APPLICATIONS

The present application is based upon and claims the benefit of priority to Japanese Patent Application No. 2024-194548, filed Nov. 6, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2015-106610 describes an electronic component-embedded substrate in which an electronic component is embedded in a cavity formed in a resin insulating layer. The entire contents of this publication are incorporated herein by reference.

### SUMMARY OF THE INVENTION

According to one aspect of the present invention, a wiring substrate includes a first resin insulating layer having a cavity, a second resin insulating layer formed on the first resin insulating layer such that the second resin insulating layer faces a first surface of the first resin insulating layer, a component accommodated in the cavity of the first resin insulating layer and including an electrode facing the second resin insulating layer, and a third resin insulating layer formed on the first resin insulating layer such that the third resin insulating layer faces a second surface of the first resin insulating layer on the opposite side with respect to the first surface of the first resin insulating layer. The second resin insulating layer is formed on the first resin insulating layer such that the second resin insulating layer closes a first-surface-side opening of the cavity formed in the first resin insulating layer and is closer to a mounting surface of an electronic component than the third resin insulating layer, the third resin insulating layer is formed on the first resin insulating layer such that the third resin insulating layer closes a second-surface-side opening of the cavity formed in the first resin insulating layer and includes a part filling a gap formed between an inner wall of the cavity and the component in the cavity, and the first resin insulating layer is formed such that the cavity has a trapezoidal cross-sectional shape having a distance between opposing legs decreasing from the second surface of the first resin insulating layer toward the first surface of the first resin insulating layer.

According to another aspect of the present invention, a method for manufacturing a wiring substrate includes forming a metal layer on a support plate, forming a first alignment mark on the metal layer, laminating a second resin insulating layer on the metal layer such that the second resin insulating layer covers the first alignment mark, forming a first conductor layer on the second resin insulating layer, forming an uppermost first resin insulating layer on the second resin insulating layer such that the uppermost first resin insulating layer covers the first conductor layer, forming a second conductor layer on the uppermost first resin insulating layer, forming a lowermost first resin insulating layer on the uppermost first resin insulating layer such that the lowermost first resin insulating layer covers the conductor layer, forming a cavity in the uppermost first resin insulating layer and the lowermost first resin insulating layer such that the cavity penetrates through the uppermost first resin insulating layer and the lowermost first resin insulating layer, accommodating a component in the cavity formed in the uppermost first resin insulating layer and the lowermost first resin insulating layer such that the component is positioned relative to the first alignment mark, forming a third resin insulating layer on the lowermost first resin insulating layer, forming a third conductor layer on the third resin insulating layer, removing the support plate and the metal layer from the second resin insulating layer, and forming an opening in the second resin insulating layer at a position relative to the first alignment mark such that the opening penetrates through the second resin insulating layer and exposes an electrode of the component.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2A is a cross-sectional view schematically illustrating a method for manufacturing a wiring substrate according to an embodiment of the present invention;

FIG. 2B is a cross-sectional view schematically illustrating a method for manufacturing a wiring substrate according to an embodiment of the present invention;

FIG. 2C is a cross-sectional view schematically illustrating a method for manufacturing a wiring substrate according to an embodiment of the present invention;

FIG. 2D is a cross-sectional view schematically illustrating a method for manufacturing a wiring substrate according to an embodiment of the present invention;

FIG. 2E is a cross-sectional view schematically illustrating a method for manufacturing a wiring substrate according to an embodiment of the present invention;

FIG. 2F is a cross-sectional view schematically illustrating a method for manufacturing a wiring substrate according to an embodiment of the present invention;

FIG. 2G is a cross-sectional view schematically illustrating a method for manufacturing a wiring substrate according to an embodiment of the present invention;

FIG. 2H is a cross-sectional view schematically illustrating a method for manufacturing a wiring substrate according to an embodiment of the present invention;

FIG. 2I is a cross-sectional view schematically illustrating a method for manufacturing a wiring substrate according to an embodiment of the present invention;

FIG. 2J is a cross-sectional view schematically illustrating a method for manufacturing a wiring substrate according to an embodiment of the present invention; and

FIG. 3 is a cross-sectional view schematically illustrating a wiring substrate of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

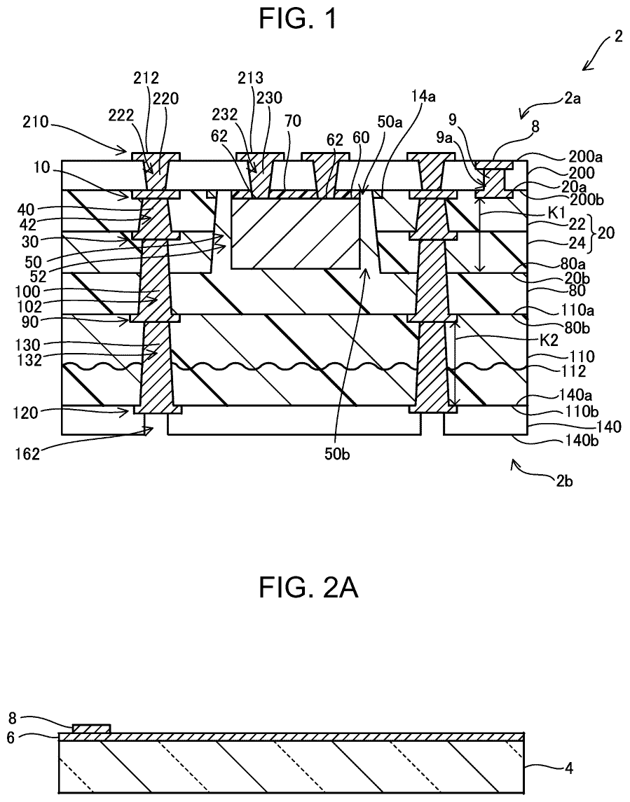

FIG. 1 is a cross-sectional view illustrating a wiring substrate 2 according to an embodiment of the present invention. As illustrated in FIG. 1, the wiring substrate 2 has an upper surface (2a) and a lower surface (2b). The upper surface (2a) is a mounting surface, on which an electronic component is mounted. Examples of electronic components include logic ICs, memories, and the like. The wiring substrate 2 includes a first resin insulating layer 20, a second resin insulating layer 200, a third resin insulating layer 80, a fourth resin insulating layer 110, and a second solder resist layer 140. An example of the second resin insulating layer 200 is a first solder resist layer. The second resin insulating layer 200 is an outermost resin insulating layer.

The first resin insulating layer 20 has a first surface (20a) and a second surface (20b) on the opposite side with respect to the first surface (20a). The second resin insulating layer 200 has a third surface (200a) and a fourth surface (200b) on the opposite side with respect to the third surface (200a). The third resin insulating layer 80 has a fifth surface (80a) and a sixth surface (80b) on the opposite side with respect to the fifth surface (80a). The fourth resin insulating layer 110 has a seventh surface (110a) and an eighth surface (110b) on the opposite side with respect to the seventh surface (110a). The second solder resist layer 140 has a ninth surface (140a) and a tenth surface (140b) on the opposite side with respect to the ninth surface (140a). The upper surface (2a) of the wiring substrate 2 and the third surface (200a) of the second resin insulating layer 200 are the same surface. The lower surface (2b) of the wiring substrate 2 and the tenth surface (140b) of the second solder resist layer 140 are the same surface. The first surface (20a) faces the fourth surface (200b) of the second resin insulating layer 200. The second surface (20b) faces the fifth surface (80a) of the third resin insulating layer 80. The first resin insulating layer 20 includes an uppermost first resin insulating layer 22 and a lowermost first resin insulating layer 24. A surface of the uppermost first resin insulating layer 22 in contact with the second resin insulating layer 200 is the first surface (20a). A surface of the lowermost first resin insulating layer 24 in contact with the third resin insulating layer 80 is the second surface (20b). The first resin insulating layer 20 may include other resin insulating layers between the uppermost first resin insulating layer 22 and the lowermost first resin insulating layer 24. The number of resin insulating layers forming the first resin insulating layer 20 may be 3 or more. The resin insulating layers forming the first resin insulating layer 20 are formed of a resin and inorganic particles dispersed in the resin. An example of the resin is a thermosetting resin. Examples of the inorganic particles include silica particles and alumina particles. The resin insulating layers forming the first resin insulating layer 20 do not have a reinforcing material made of fiber. An example of the reinforcing material is glass cloth. The second resin insulating layer 200 and the third resin insulating layer 80 do not have a reinforcing material.

The wiring substrate 2 further has conductor layers (10, 30) and via conductors 40. The conductor layers (10, 30) and the resin insulating layers (22, 24) are alternately laminated. The via conductors 40 penetrate the resin insulating layer 22 sandwiched between adjacent conductor layers (10, 30) and connect the adjacent conductor layers (10, 30). The conductor layer 10 is formed between the first surface (20a) of the first resin insulating layer 20 and the fourth surface (200b) of the second resin insulating layer 200. The conductor layer 10 is sandwiched between the second resin insulating layer 200 and the uppermost first resin insulating layer 22. The conductor layer 10 includes a frame-shaped cavity conductor circuit (14a). The conductor layer 30 is formed between the uppermost first resin insulating layer 22 and the lowermost first resin insulating layer 24. The conductor layer 30 is sandwiched between the uppermost first resin insulating layer 22 and the lowermost first resin insulating layer 24. The via conductors 40 connect the conductor layer 10 and the conductor layer 30. The via conductors 40 are respectively formed in openings 42 that penetrate the uppermost first resin insulating layer 22.

The first resin insulating layer 20 has a cavity 50 extending from the first surface (20a) to the second surface (20b). The cavity 50 penetrates the first resin insulating layer 20 and the cavity conductor circuit (14a). The cavity 50 has an opening (50a) on the first surface (20a) side formed on the first surface (20a), and an opening (50b) on the second surface (20b) side formed on the second surface (20b). A component 60 is accommodated in the cavity 50. An adhesive film 70 is formed between the component 60 and the fourth surface (200b) of the second resin insulating layer 200. The component 60 is fixed to the fourth surface (200b) of the second resin insulating layer 200 by the adhesive film 70. The component 60 has electrodes 62 facing the fourth surface (200b). The second resin insulating layer 200 closes the opening (50a) on the first surface (20a) side. The third resin insulating layer 80 closes the opening (50b) on the second surface (20b) side. A part of the third resin insulating layer 80 fills a gap 52 between an inner wall of the cavity 50 and the component 60.

The cavity 50 has a substantially trapezoidal cross-sectional shape. A distance between opposing legs (inter-leg distance) substantially decreases from the second surface (20b) toward the first surface (20a). Among four sides of the trapezoid, the legs are sides other than upper and lower bases. The inter-leg distance substantially decreases toward the mounting surface. A size of the opening (50a) on the first surface (20a) side of the cavity 50 is smaller than a size of the opening (50b) on the second surface (20b) side.

The third resin insulating layer 80 is formed on the second surface (20b) of the first resin insulating layer 20. The fifth surface (80a) faces the second surface (20b) of the first resin insulating layer 20. The sixth surface (80b) faces the seventh surface (110a) of the fourth resin insulating layer 110. The third resin insulating layer 80 is formed of a resin and inorganic particles dispersed within the resin.

The wiring substrate 2 further has a conductor layer 90 and via conductors 100. The conductor layer 90 is formed on the sixth surface (80b) of the third resin insulating layer 80. The via conductors 100 connect the conductor layer 30 and the conductor layer 90. The via conductors 100 are respectively formed in openings 102 that penetrate the third resin insulating layer 80 and the lowermost first resin insulating layer 24. The openings 102 penetrate only the third resin insulating layer 80 and the lowermost first resin insulating layer 24. Each via conductor 100 is an example of a second via conductor.

The fourth resin insulating layer 110 is formed on the sixth surface (80b) of the third resin insulating layer 80 and on the conductor layer 90. The fourth resin insulating layer 110 is in contact with the second solder resist layer 140 and is formed on an inner side of the second solder resist layer 140. The seventh surface (110a) faces the sixth surface (80b) of the third resin insulating layer 80. The eighth surface (110b) faces the ninth surface (140a) of the second solder resist layer 140. The fourth resin insulating layer 110 is formed of a resin and inorganic particles dispersed in the resin. The fourth resin insulating layer 110 may further have a reinforcing material 112. The reinforcing material 112 is contained only in the fourth resin insulating layer 110. The first resin insulating layer 20, the third resin insulating layer 80, the second resin insulating layer 200, and the second solder resist layer 140 do not contain a reinforcing material. The fourth resin insulating layer 110 is formed, for example, using a prepreg. A thickness of a resin insulating layer containing the reinforcing material 112 is greater than a distance between the first surface (20a) and the second surface (20b) of the first resin insulating layer 20 (that is, a thickness of the first resin insulating layer 20) (Relation 1). An example of a resin insulating layer containing the reinforcing material 112 is the fourth resin insulating layer 110. The resin insulating layer containing the reinforcing material 112 is in contact with the second solder resist layer 140. The thickness of the first resin insulating layer 20 may be a distance between the conductor layer 10 in contact with the first surface (20a) and the second surface (20b) (K1 in FIG. 1). A thickness of the fourth resin insulating layer 110 is represented by a distance between the conductor layers sandwiching the fourth resin insulating layer 110. A thickness of a resin insulating layer containing the reinforcing material 112 is represented by a distance between conductor layers sandwiching the resin insulating layer containing the reinforcing material 112 (K2 in FIG. 1). When there are two or more resin insulating layers containing a reinforcing material, one layer satisfies Relation 1. Alternatively, two layers satisfy Relation 1. Alternatively, all of the layers satisfy Relation 1. The wiring substrate 2 further has a conductor layer 120 and via conductors 130. The conductor layer 120 is formed on the eighth surface (110b) of the fourth resin insulating layer 110. The via conductors 130 are respectively formed in openings 132 that penetrate the fourth resin insulating layer 110. The via conductors 130 connect the conductor layer 90 and the conductor layer 120.

The second solder resist layer 140 is formed on the eighth surface (110b) of the fourth resin insulating layer 110 and on the conductor layer 120. The second solder resist layer 140 is formed at a position farthest from the second resin insulating layer 200. The ninth surface (140a) faces the eighth surface (110b) of the fourth resin insulating layer 110. The tenth surface (140b) forms the lower surface (2b) of the wiring substrate 2. The second solder resist layer 140 has openings 162 that expose the conductor layer 120.

The second resin insulating layer 200 is formed on the first surface (20a) of the first resin insulating layer 20. The second resin insulating layer 200 is formed on the first resin insulating layer 20 such that the fourth surface (200b) faces the first surface (20a).

The wiring substrate 2 further has a conductor layer 210 and via conductors (220, 230). The conductor layer 210 is formed on the third surface (200a) of the second resin insulating layer 200. The conductor layer 210 includes mounting electrodes (212, 213). An alignment mark (first alignment mark) 8 is formed on the third surface (200a) of the second resin insulating layer 200. The conductor layer 210 and the alignment mark 8 are not formed simultaneously. The two are formed separately. The alignment mark 8 is embedded in the second resin insulating layer 200. The conductor layer 210, which includes the mounting electrodes (212, 213), is not embedded in the second resin insulating layer 200. The conductor layer 210 protrudes from the second resin insulating layer 200. A conductor 9 is formed in an opening (9a) that penetrates the second resin insulating layer 200. The conductor 9 connects the first alignment mark 8 and the conductor layer 10. The via conductors 220 are respectively formed in openings 222 that penetrate the second resin insulating layer 200. The openings 222 expose the conductor layer 10. The via conductors 220 connect the mounting electrodes 212 to the conductor layer 10. The via conductors 230 are respectively formed in openings 232 that penetrate the second resin insulating layer 200 and the adhesive film 70. The openings 232 expose the electrodes 62 of the component 60. The via conductors 230 connect the mounting electrodes 213 to the electrodes 62. The via conductors 230 are each an example of a first via conductor. A tin plating layer may be formed on an upper surface of the conductor layer 210. The mounting electrodes (212, 213) function as bumps for mounting an electronic component.

The second resin insulating layer 200 has the openings (222, 232, 9a) that penetrate the second resin insulating layer 200. Lengths of the openings (222, 232, 9a) are different from each other. A length of each of the openings 232 is longer than a length of each of the openings 222. The length of each of the openings 222 is longer than a length of the opening 9a. The length of each of the openings 222 is a distance between the third surface (200a) and the fourth surface (200b). The length of each of the openings 232 is a distance between the third surface (200a) and the electrodes 62. The length of the opening (9a) is a distance between the alignment mark 8 and the fourth surface (200b). As described above, the second resin insulating layer 200 has three types of openings (222, 232, 9a), and the lengths of the three types of openings (222, 232, 9a) are different from each other.

### Method for Manufacturing Wiring Substrate

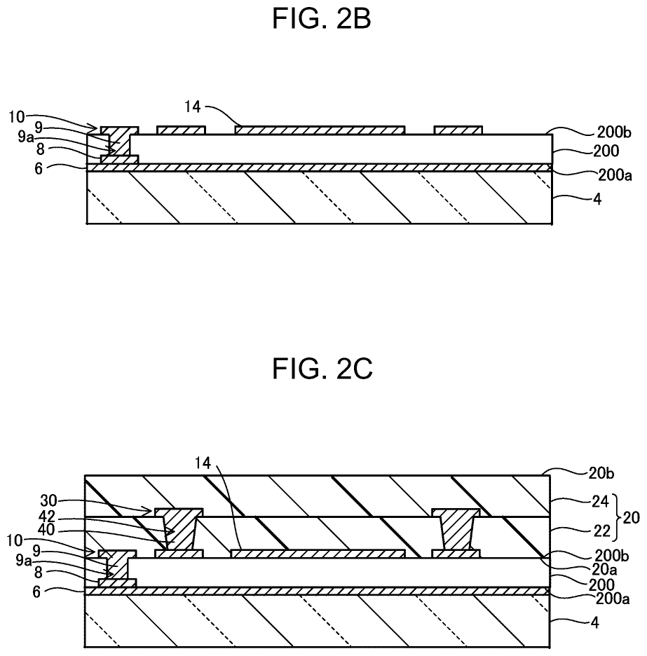

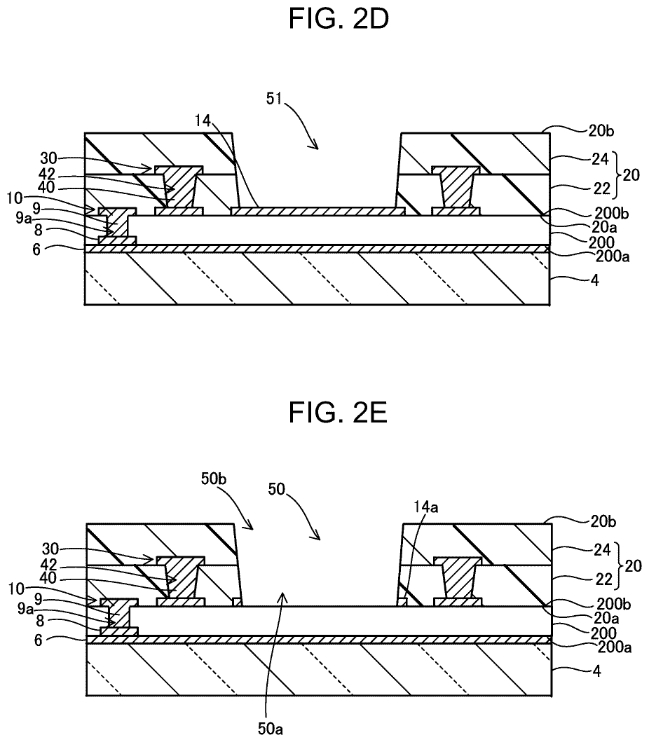

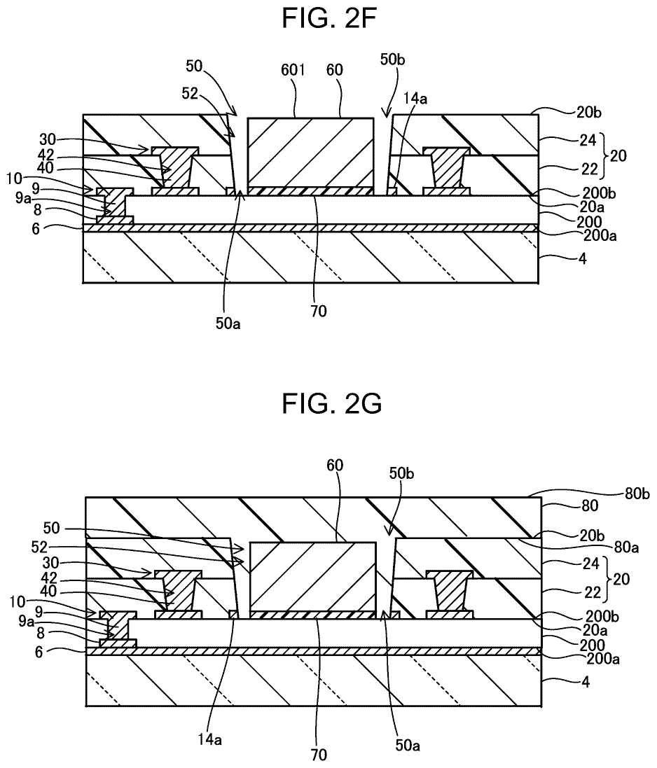

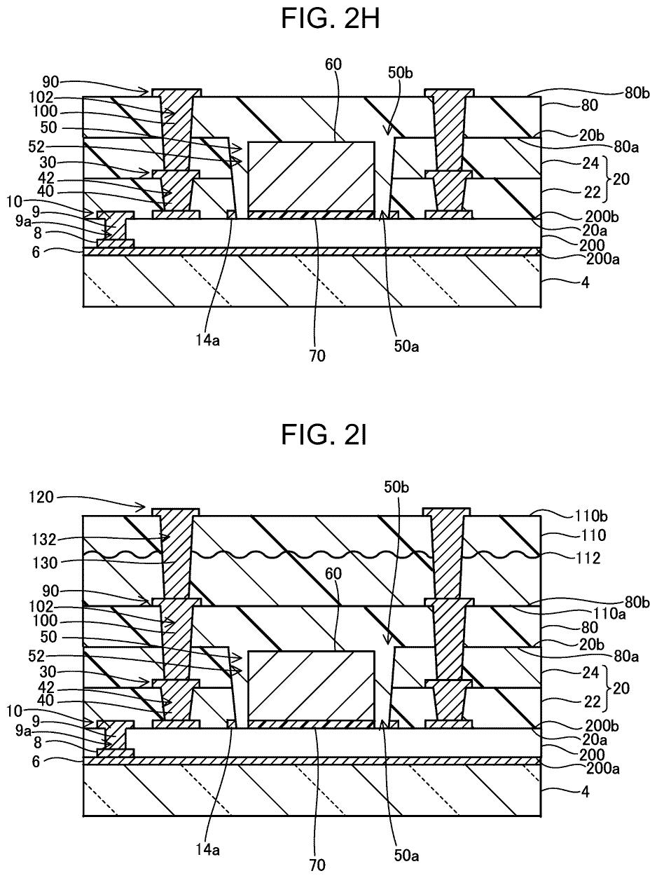

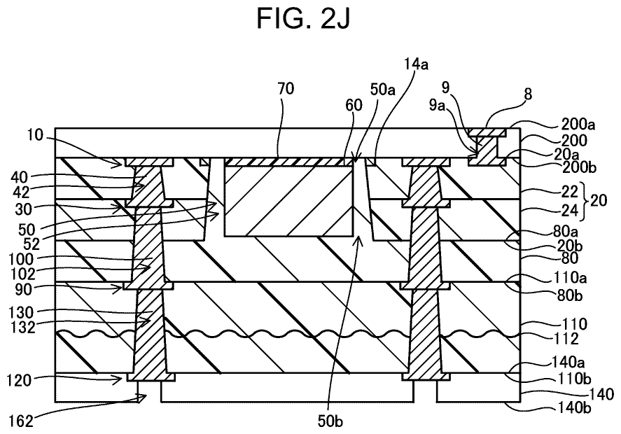

FIGS. 2A-2J illustrate a method for manufacturing the wiring substrate 2 according to an embodiment of the present invention. FIGS. 2A-2J are cross-sectional views. In FIGS. 2A to 2I, an up-down direction in the drawings is opposite to that in FIGS. 1 and 2J. FIG. 2A illustrates a support plate 4, a metal layer 6 formed on the support plate 4, and the alignment mark (first alignment mark) 8 formed on the metal layer 6. The metal layer 6 is, for example, a copper foil. The metal layer 6 is formed in advance on the support plate 4. A plating resist is formed on the metal layer 6. The alignment mark 8 is formed on the metal layer 6 exposed from the plating resist by electrolytic copper plating. It is preferable that no conductor circuit other than the alignment mark 8 is formed on the metal layer 6. The metal layer 6 serves as a seed layer for forming the alignment mark 8. After that, the plating resist is removed.

The second resin insulating layer 200 is formed on the metal layer 6 and the alignment mark 8. The second resin insulating layer 200 has the third surface (200a) and the fourth surface (200b) on the opposite side with respect to the third surface (200a). The third surface (200a) of the second resin insulating layer 200 faces the metal layer 6. The opening (9a) that penetrates the second resin insulating layer 200 and exposes the alignment mark 8 is formed in the second resin insulating layer 200. The opening (9a) is formed using the alignment mark 8 as a reference. The opening (9a) is formed using laser beam or photolithography. The opening (9a) penetrates only the second resin insulating layer 200. A seed layer is formed on the fourth surface (200b) of the second resin insulating layer 200 and in the opening (9a). Using the alignment mark 8 as a reference, a plating resist is formed on the seed layer. A plating resist may be formed on the seed layer using the opening (9a) as a reference. An electrolytic copper plating layer is formed on the seed layer exposed from the plating resist. The plating resist is removed. The seed layer exposed from the electrolytic copper plating layer is removed. As illustrated in FIG. 2B, the conductor layer 10 is formed on the fourth surface (200b) of the second resin insulating layer 200. The conductor layer 10 includes a cavity conductor circuit 14. The conductor layer 10 may include an alignment mark (second alignment mark). A position of each conductor circuit in the conductor layer 10 is related to a position of the first alignment mark 8. The cavity conductor circuit 14 and the second alignment mark are included in the conductor circuits in the conductor layer 10. The position of the first alignment mark 8 and a position of the second alignment mark are related to each other. The position of the first alignment mark 8 and a position of the cavity conductor circuit 14 are related to each other. The cavity conductor circuit 14 serves as a stopper for forming the cavity 50. A size of the cavity conductor circuit 14 is preferably larger than the size of the opening (50a) on the first surface (20a) side of the cavity 50. At the same time as the conductor layer 10, the conductor 9 that fills the opening (9a) is formed. The conductor 9 connects the alignment mark 8 and the conductor layer 10.

The uppermost first resin insulating layer 22 is formed on the conductor layer 10 and on the fourth surface (200b) of the second resin insulating layer 200. Laser is irradiated onto the uppermost first resin insulating layer 22. The laser is irradiated based on the positions of the conductor circuits in the conductor layer 10. For example, the laser is irradiated based on the second alignment mark. The laser penetrates the uppermost first resin insulating layer 22. The openings 42 for the via conductors 40 that penetrate the uppermost first resin insulating layer 22 and expose the conductor layer 10 are formed in the uppermost first resin insulating layer 22. Positions of the openings 42 for the via conductors 40 are related to the position of the first alignment mark 8. A seed layer is formed on the uppermost first resin insulating layer 22 and in the openings 42. A plating resist is formed on the seed layer based on the positions of the conductor circuits in the conductor layer 10. For example, the plating resist is formed based on the second alignment mark. An electrolytic copper plating layer is formed on the seed layer exposed from the plating resist. The plating resist is removed. The seed layer exposed from the electrolytic copper plating layer is removed. The conductor layer 30 and the via conductors 40 are formed at the same time. The conductor layer 30 may have a third alignment mark. A position of each conductor circuit in the conductor layer 30 is related to the position of the first alignment mark 8. A position of the third alignment mark is related to the position of the first alignment mark 8. Positions of the via conductors 40 are related to the position of the first alignment mark 8. The via conductors 40 respectively fill the openings 42. The via conductors 40 connect the conductor layer 10 and the conductor layer 30. The lowermost first resin insulating layer 24 is formed on the uppermost first resin insulating layer 22 and the conductor layer 30. As illustrated in FIG. 2C, the first resin insulating layer 20 is formed on the fourth surface (200b) of the second resin insulating layer 200 and on the conductor layer 10. The first resin insulating layer 20 has the first surface (20a) and the second surface (20b) on the opposite side with respect to the first surface (20a). The first surface (20a) of the first resin insulating layer 20 faces the fourth surface (200b) of the second resin insulating layer 200. The first resin insulating layer 20 is formed of the uppermost first resin insulating layer 22 and the lowermost first resin insulating layer 24. The conductor layer 30 is sandwiched between the uppermost first resin insulating layer 22 and the lowermost first resin insulating layer 24. The uppermost first resin insulating layer 22 and the lowermost first resin insulating layer 24 each have a first surface and a second surface on the opposite side with respect to the first surface. The first surface of the uppermost first resin insulating layer 22 faces the fourth surface (200b) of the second resin insulating layer 200. The first surface of the uppermost first resin insulating layer 22 and the first surface (20a) of the first resin insulating layer 20 form the same surface. The first surface of the lowermost first resin insulating layer 24 faces the second surface of the uppermost first resin insulating layer 22. The second surface of the lowermost first resin insulating layer 24 and the second surface (20b) of the first resin insulating layer 20 form the same surface. A thickness of the uppermost first resin insulating layer 22 is preferably greater than a thickness of the lowermost first resin insulating layer 24. A ratio of the thickness of the uppermost first resin insulating layer 22 to the thickness of the lowermost first resin insulating layer 24 ((the thickness of the uppermost first resin insulating layer 22)/(the thickness of the lowermost first resin insulating layer 24)) is preferably 1.2 or more and 1.5 or less. The thickness of the uppermost first resin insulating layer 22 is a distance between the conductor layer 10 and the conductor layer 30. The uppermost first resin insulating layer 22 is sandwiched between the conductor layer 10 and the conductor layer 30. The thickness of the lowermost first resin insulating layer 24 is a distance between the conductor layer 30 and the second surface of the lowermost first resin insulating layer 24. The conductor layer 30 is sandwiched between the uppermost first resin insulating layer 22 and the lowermost first resin insulating layer 24.

Laser is irradiated from above the second surface (20b) of the first resin insulating layer 20. The laser is irradiated based on the positions of the conductor circuits in the conductor layer 30. For example, the laser is irradiated based on the third alignment mark. The laser penetrates the first resin insulating layer 20. As illustrated in FIG. 2D, an opening 51 that penetrates the first resin insulating layer 20 and reaches the cavity conductor circuit 14 is formed. The laser penetrates all the resin insulating layers (22, 24) belonging to the first resin insulating layer 20 and reaches the cavity conductor circuit 14. The cavity conductor circuit 14 is exposed from the opening 51. A position of the opening 51 is related to the position of the first alignment mark 8. The cavity conductor circuit 14 prevents the laser from reaching the second resin insulating layer 200. For example, the laser may be irradiated obliquely to the cavity conductor circuit 14 so that a wall surface of the opening 51 is formed obliquely with respect to the cavity conductor circuit 14. A cross-sectional shape of the opening 51 is formed substantially trapezoidal. The cross-sectional shape of the opening 51 illustrated in FIG. 2D is substantially an inverted trapezoid. A distance between opposing legs substantially decreases from the second surface (20b) toward the first surface (20a).

The cavity conductor circuit 14 exposed from the opening 51 is removed by etching. The cavity conductor circuit (14a) after the etching has a frame-shaped planar shape. The frame-shaped cavity conductor circuit (14a) is covered by the uppermost first resin insulating layer 22. As illustrated in FIG. 2E, the cavity 50 penetrating both the first resin insulating layer 20 and the cavity conductor circuit (14a) is formed. The cavity 50 is formed to have a substantially trapezoidal cross-sectional shape. The cross section of the cavity 50 illustrated in FIG. 2E is substantially an inverted trapezoid. A distance between opposing legs substantially decreases from the second surface (20b) toward the first surface (20a). The size of the opening (50a) on the first surface (20a) side is smaller than the size of the opening (50b) on the second surface (20b) side. The fourth surface (200b) of the second resin insulating layer (200) is exposed from the cavity (50). The second resin insulating layer (200) closes the opening (50a) on the first surface (20a) side of the cavity (50). The opening (50a) of the cavity (50) is closed by the fourth surface (200b) of the second resin insulating layer (200). The second resin insulating layer (200) is an example of a member that closes the opening (50a).

As illustrated in FIG. 2F, the component 60 is fixed on the fourth surface (200b) of the second resin insulating layer 200, which is exposed from the cavity 50, via the adhesive film 70. For example, the component 60 is fixed on the fourth surface (200b) of the second resin insulating layer 200 based on the third alignment mark. Alternatively, the component 60 is fixed on the fourth surface (200b) of the second resin insulating layer 200 based on a position of the cavity 50. A position of the component 60 is related to the position of the first alignment mark 8. The adhesive film 70 is attached in advance to the component 60. The component 60 with the adhesive film 70 is fixed on the fourth surface (200b) exposed from the cavity 50. The component 60 is fixed in the cavity 50. When the component 60 is fixed, the component 60 is at the same time surrounded by the first resin insulating layer 20. The component 60 is protected by the first resin insulating layer 20. An upper surface 601 of the component 60 does not protrude from the opening (50b). The upper surface 601 of the component 60 is positioned below the second surface (20b) of the first resin insulating layer 20. The upper surface 601 of the component 60 is not positioned above the second surface (20b) of the first resin insulating layer 20. It is preferable that the upper surface 601 of the component 60 be positioned above the first surface of the lowermost first resin insulating layer 24. The upper surface 601 of the component 60 is positioned between the first surface and the second surface of the lowermost first resin insulating layer 24. The gap 52 is formed between the component 60 and the inner wall surface of the cavity 50.

As illustrated in FIG. 2G, the third resin insulating layer 80 is formed on the second surface (20b) of the first resin insulating layer 20. The third resin insulating layer 80 has the fifth surface (80a) and the sixth surface (80b) on the opposite side with respect to the fifth surface (80a). The fifth surface (80a) of the third resin insulating layer 80 faces the second surface (20b). The third resin insulating layer 80 closes the opening (50b) on the second surface (20b) side of the cavity 50. The opening (50b) of the cavity 50 is closed by the fifth surface (80a) of the third resin insulating layer 80. The third resin insulating layer 80 fills the gap 52.

Laser (first laser) is irradiated from above the sixth surface (80b) of the third resin insulating layer 80 based on the positions of the conductor circuits in the conductor layer 30. For example, the first laser is irradiated based on the third alignment mark. The first laser penetrates the third resin insulating layer 80 and the lowermost first resin insulating layer 24 at the same time. The openings 102 that penetrate the third resin insulating layer 80 and the lowermost first resin insulating layer 24 and reach the conductor layer 30 are formed. As illustrated in FIG. 2H, the conductor layer 90 is formed on the sixth surface (80b) of the third resin insulating layer 80. The via conductors 100 are simultaneously formed with the conductor layer 90. For example, the conductor layer 90 and the via conductors 100 are formed using a semi-additive method. The via conductors 100 respectively fill the openings 102. The via conductors 100 connect the conductor layer 30 and the conductor layer 90.

When the component 60 has electrodes on both front and back sides, laser (second laser) is irradiated toward the component 60 from the sixth surface (80b) of the third resin insulating layer 80 based on the positions of the conductor circuits in the conductor layer 30. For example, the second laser is irradiated based on the third alignment mark. The second laser penetrates only the third resin insulating layer 80. The second laser does not penetrate the lowermost first resin insulating layer 24. Via conductor openings that penetrate the third resin insulating layer 80 and reach the component 60 are formed in the third resin insulating layer 80. The via conductor openings that penetrate only the third resin insulating layer 80 reach the electrodes of the component 60. The third resin insulating layer 80 can have two types of via conductor openings. The two types of openings (the openings that reach the conductor layer 30 and the openings that reach the electrodes of the component) have different depths. When the via conductors 100 are formed, via conductors that connect the component 60 and the conductor layer 90 are formed in the via conductor openings that expose the electrodes of the component 60.

The fourth resin insulating layer 110 is formed on the sixth surface (80b) of the third resin insulating layer 80 and on the conductor layer 90. The seventh surface (110a) of the fourth resin insulating layer 110 faces the sixth surface (80b). The fourth resin insulating layer 110 contains the reinforcing material 112. The openings 132 are formed in the fourth resin insulating layer 110. As illustrated in FIG. 2I, the conductor layer 120 is formed on the eighth surface (110b) of the fourth resin insulating layer 110. For example, the conductor layer 120 and the via conductors 130 are formed using a semi-additive method. The via conductors 130 are simultaneously formed with the conductor layer 120. The via conductors 130 respectively fill the openings 132. The via conductors 130 connect the conductor layer 90 and the conductor layer 120.

In the embodiment, a resin insulating layer (additional resin insulating layer) containing a reinforcing material can be added between the third resin insulating layer 80 and the fourth resin insulating layer 110. A conductor layer is formed between the additional resin insulating layer and the fourth resin insulating layer 110. Via conductors penetrating the additional resin insulating layer are formed. A thickness of a resin insulating layer containing a reinforcing material, such as the fourth resin insulating layer 110, is preferably greater than the thickness of the first resin insulating layer 20.

The support plate 4 and the metal layer 6 are removed. The third surface (200a) of the second resin insulating layer 200 is exposed. The alignment mark 8 is exposed. The second solder resist layer 140 is formed on the eighth surface (110b) of the fourth resin insulating layer 110. The second solder resist layer 140 is preferably formed directly on the fourth resin insulating layer 110. The ninth surface (140a) and the eighth surface (110b) are in contact with each other. The ninth surface (140a) of the second solder resist layer 140 faces the eighth surface (110b). As illustrated in FIG. 2J, the openings 162 exposing the conductor layer 120 are formed in the second solder resist layer 140. For example, the openings 162 are formed using photolithography.

Laser (third laser) is irradiated from above the third surface (200a) of the second resin insulating layer 200. The third laser is irradiated based on the first alignment mark 8. The third laser simultaneously penetrates the second resin insulating layer 200 and the adhesive film 70. The openings 232 are formed. Positions of the opening 232 are related to the position of the first alignment mark 8. The openings 232 penetrate the second resin insulating layer 200 and the adhesive film 70 to expose the electrodes 62 of the component 60. Positions of the openings 232 are related to the position of the component 60. Therefore, the positions of the electrodes 62 of the component 60 and the positions of the openings 232 match with a high degree of accuracy. Further, laser (fourth laser) is irradiated from above the third surface (200a) of the second resin insulating layer 200. The fourth laser is irradiated based on the first alignment mark 8. The fourth laser penetrates the second resin insulating layer 200. The fourth laser penetrates only the second resin insulating layer 200. The openings 222 are formed. The openings 222 penetrate only the second resin insulating layer 200. Positions of the openings 222 are related to the position of the first alignment mark 8. The openings 222 penetrate the second resin insulating layer 200 to expose the conductor layer 10. The conductor layer 210 is formed on the third surface (200a). The conductor layer 210 includes the mounting electrodes (212, 213). The via conductors (220, 230) are simultaneously formed with the conductor layer 210. At this time, the alignment mark 8 has already been formed. The conductor layer 210 and the alignment mark 8 are not formed simultaneously. The conductor layer 210 and the alignment mark 8 are formed separately. The via conductors 220 respectively fill the openings 222. The via conductors 220 connect the conductor layer 10 and the mounting electrodes 212. The via conductors 230 respectively fill the openings 232. The via conductors 230 connect the electrodes 62 and the mounting electrodes 213. The positions of the openings 232 are related to the position of the component 60. Therefore, the wiring substrate 2 of the embodiment can achieve high connection reliability between the via conductors 230 and the electrodes 62 of the component 60. The wiring substrate 2 manufactured in the embodiment can improve connection reliability between an electronic component and the component 60 via the mounting electrodes 213 and via conductors 230. A tin-plated layer is formed on the upper surface of the conductor layer 210. The wiring substrate 2 of the embodiment is obtained.

In the wiring substrate 2 of the embodiment, the cross-sectional shape of the cavity 50 is substantially trapezoidal, and the distance between the opposing legs substantially decreases from the second surface (20b) toward the first surface (20a) of the first resin insulating layer 20. A space between the inner wall of the cavity 50 and the component 60 in the cavity 50 substantially decreases from the second surface (20b) toward the first surface (20a). A size of an outlet of the space on the second surface (20b) side is larger than a size of an outlet of the space on the first surface (20a) side. Even when resin in the space expands due to thermal shock or the like, the expanded resin is unlikely to escape to outside of the space through the outlet on the first surface (20a) side. The expanded resin is unlikely to escape to the outside of the space through the opening (50a) on the first surface (20a) side. The expanded resin is unlikely to press against the second resin insulating layer 200. Flatness of the mounting surface is unlikely to decrease. When an electronic component is mounted on the wiring substrate 2 of the embodiment, the electronic component is easily mounted. The embodiment can improve connection reliability between the wiring substrate 2 of the embodiment and an electronic component mounted on the wiring substrate 2 of the embodiment. The connection reliability between the wiring substrate 2 of the embodiment and an electronic component mounted on the wiring substrate 2 of the embodiment is unlikely to decrease due to thermal shock. The embodiment can provide a wiring substrate 2 having stable performance.

The via conductors (220, 230) that penetrate the second resin insulating layer 200 are tapered toward the lower surface (2b) of the wiring substrate 2. The via conductors (40, 100, 130) that penetrate the resin insulating layers (22, 24, 80, 110) other than the second resin insulating layer 200 are tapered toward the upper surface (2a) of the wiring substrate 2. The orientation of the via conductors penetrating the second resin insulating layer 200 is opposite to the orientation of the via conductors penetrating the resin insulating layers other than the second resin insulating layer 200.

### Wiring Substrate and Manufacturing Method

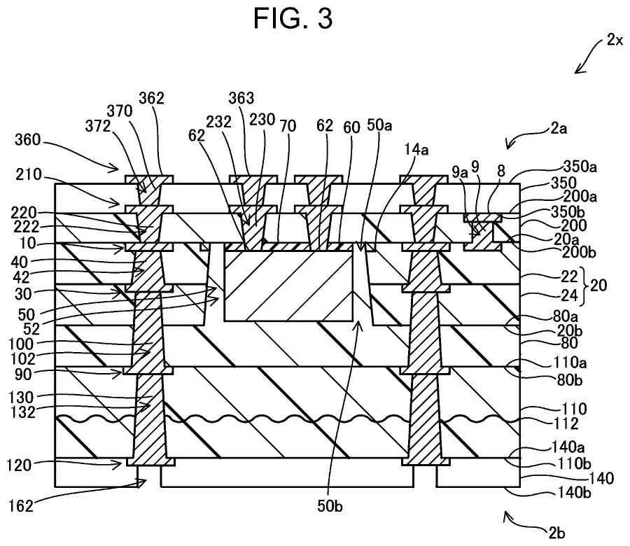

FIG. 3 is a cross-sectional view illustrating a wiring substrate (2x) of a modified example according to an embodiment of the present invention. When elements forming the wiring substrate (2x) of the modified example are the same as elements forming the wiring substrate 2 of the embodiment, the same reference numeral symbols are used in the figure. Detailed description of elements common to the embodiment is omitted. The wiring substrate (2x) of the modified example is obtained by additionally providing a first solder resist layer 350, a conductor layer 360, and via conductors 370 to the wiring substrate 2 of the embodiment. The first solder resist layer 350 is formed on the second resin insulating layer 200, the conductor layer 210, and the alignment mark 8. No tin plating layer is formed on the conductor layer 210. The conductor layer 360 is formed on the first solder resist layer 350. The via conductors 370 penetrating the first solder resist layer 350 and connecting the conductor layer 210 and the conductor layer 360 are formed. The conductor layer 360 and the via conductors 370 are formed at the same time using a semi-additive method. In the embodiment, the second resin insulating layer 200 also serves as a first solder resist layer, whereas in the modified example, the first solder resist layer 350 is provided separately from the second resin insulating layer 200. In the embodiment, the conductor layer 210 includes a conductor circuit for mounting an electronic component, whereas in the modified example, the conductor layer 210 does not include a conductor circuit for mounting an electronic component. In the modified example, the conductor layer 360 includes a conductor circuit for mounting an electronic component. In the embodiment, the second resin insulating layer 200 is one of the outermost resin insulating layers, whereas in the modified example, the first solder resist layer 350 is one of the outermost resin insulating layers.

The first solder resist layer 350 is formed on the third surface (200a) of the second resin insulating layer 200. The first solder resist layer 350 has an eleventh surface (350a) and a twelfth surface (350b) on the opposite side with respect to the eleventh surface (350a). The twelfth surface (350b) faces the third surface (200a). The upper surface (2a) of the wiring substrate (2x) of the modified example is the same surface as the eleventh surface (350a) of the first solder resist layer 350. The first solder resist layer 350 does not contain a reinforcing material. The reinforcing material 112 is contained only in the fourth resin insulating layer 110. The first resin insulating layer 20, the third resin insulating layer 80, the second resin insulating layer 200, the first solder resist layer 350, and the second solder resist layer 140 do not contain a reinforcing material. The conductor layer 360 is formed on the eleventh surface (350a) of the first solder resist layer 350. The conductor layer 360 includes mounting electrodes (362, 363). The via conductors 370 are respectively formed in openings 372 penetrating the first solder resist layer 350. The openings 372 expose the conductor layer 210. A tin plating layer may be formed on an upper surface of the conductor layer 360. The mounting electrodes (362, 363) function as bumps for mounting an electronic component.

Also in the wiring substrate (2x) of the modified example, the cross-sectional shape of the cavity 50 is substantially trapezoidal, and the distance between the opposing legs substantially decreases from the second surface (20b) toward the first surface (20a) of the first resin insulating layer 20. The wiring substrate (2x) of the modified example has the same effect as the wiring substrate 2 of the embodiment.

In the embodiment and the modified example, the orientations of the via conductors are the same. The via conductors 370 penetrating the first solder resist layer 350 each taper toward the lower surface (2b) of the wiring substrate (2x). In the embodiment and the modified example, the orientation of the via conductors positioned above the first surface (20a) of the first resin insulating layer 20 is opposite to the orientation of the via conductors positioned below the first surface (20a) of the first resin insulating layer 20.

In the embodiment and the modified example, matters relating to thickness and length are the same. In the embodiment and the modified example, relationships relating to thickness and length are the same.

Japanese Patent Application Laid-Open Publication No. 2015-106610 describes an electronic component-embedded substrate in which an electronic component is embedded in a cavity formed in a resin insulating layer.

As illustrated in FIG. 1 of Japanese Patent Application Laid-Open Publication No. 2015-106610, the electronic component-embedded substrate of Japanese Patent Application Laid-Open Publication No. 2015-106610 includes a core substrate and an upper build-up layer. An electronic component is accommodated in a cavity in the upper build-up layer. A cross-sectional shape of the cavity is illustrated in FIG. 5B of Japanese Patent Application Laid-Open Publication No. 2015-106610. According to FIG. 5B of Japanese Patent Application Laid-Open Publication No. 2015-106610, wall surfaces of the cavity are inclined. And, a distance between opposing wall surfaces decreases toward the core substrate. Therefore, as a description of the cross-sectional shape of the cavity of Japanese Patent Application Laid-Open Publication No. 2015-106610, it is thought appropriate to describe the shape as an inverted trapezoid. When the electronic component-embedded substrate of Japanese Patent Application Laid-Open Publication No. 2015-106610 is subjected to thermal shock, it is thought that flatness of an upper surface of the upper build-up layer decreases.

A wiring substrate according to an embodiment of the present invention includes: a first resin insulating layer that has a first surface, a second surface on the opposite side with respect to the first surface, and a cavity extending from the first surface to the second surface; a second resin insulating layer that has a third surface and a fourth surface on the opposite side with respect to the third surface, and is formed on the first resin insulating layer such that the fourth surface faces the first surface; a component that has an electrode facing the fourth surface and is accommodated in the cavity; and a third resin insulating layer that has a fifth surface and a sixth surface on the opposite side with respect to the fifth surface, and is formed on the first resin insulating layer such that the fifth surface faces the second surface. The cavity has a first-surface-side opening formed on the first surface and a second-surface-side opening formed on the second surface. The second resin insulating layer closes the first-surface-side opening, and the third resin insulating layer closes the second-surface-side opening. The second resin insulating layer is closer to a mounting surface for mounting an electronic component than the third resin insulating layer. A part of the third resin insulating layer fills a gap between an inner wall of the cavity and the component in the cavity. A cross-sectional shape of the cavity is substantially trapezoidal, and a distance between opposing legs substantially decreases from the second surface toward the first surface.

In a wiring substrate according to an embodiment of the present invention, the cross-sectional shape of the cavity is substantially trapezoidal, and the distance between the opposing legs substantially decreases from the second surface toward the first surface of the first resin insulating layer. A space between the inner wall of the cavity and the component in the cavity substantially decreases from the second surface toward the first surface. A size of an outlet of the space on the second surface side is larger than a size of an outlet of the space on the first surface side. Even when resin in the space expands due to thermal shock or the like, the expanded resin is unlikely to escape to outside of the space through the outlet on the first surface side. The expanded resin is unlikely to press against the second resin insulating layer. Flatness of the mounting surface is unlikely to decrease. When an electronic component is mounted on the wiring substrate of the embodiment, the electronic component is easily mounted. The embodiment can improve connection reliability between the wiring substrate of the embodiment and an electronic component mounted on the wiring substrate of the embodiment. The connection reliability between the wiring substrate of the embodiment and an electronic component mounted on the wiring substrate of the embodiment is unlikely to decrease due to thermal shock. The embodiment can provide a wiring substrate having stable performance.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first resin insulating layer having a cavity;
a second resin insulating layer formed on the first resin insulating layer such that the second resin insulating layer faces a first surface of the first resin insulating layer;
a component accommodated in the cavity of the first resin insulating layer and comprising an electrode facing the second resin insulating layer; and
a third resin insulating layer formed on the first resin insulating layer such that the third resin insulating layer faces a second surface of the first resin insulating layer on an opposite side with respect to the first surface of the first resin insulating layer,
wherein the second resin insulating layer is formed on the first resin insulating layer such that the second resin insulating layer closes a first-surface-side opening of the cavity formed in the first resin insulating layer and is closer to a mounting surface of an electronic component than the third resin insulating layer, the third resin insulating layer is formed on the first resin insulating layer such that the third resin insulating layer closes a second-surface-side opening of the cavity formed in the first resin insulating layer and includes a part filling a gap formed between an inner wall of the cavity and the component in the cavity, and the first resin insulating layer is formed such that the cavity has a trapezoidal cross-sectional shape having a distance between opposing legs decreasing from the second surface of the first resin insulating layer toward the first surface of the first resin insulating layer.

2. The wiring substrate according to claim 1, wherein the first resin insulating layer includes a plurality of resin insulating layers comprising an uppermost first resin insulating layer in contact with the second resin insulating layer and a lowermost first resin insulating layer in contact with the third resin insulating layer.

3. The wiring substrate according to claim 1, wherein the second resin insulating layer is forming an outermost resin insulating layer.

4. The wiring substrate according to claim 3, wherein the outermost resin insulating layer is a first solder resist layer.

5. The wiring substrate according to claim 1, further comprising:
an outermost resin insulating layer formed on the second resin insulating layer such that the outermost resin insulating layer is in contact with the second resin insulating layer.

6. The wiring substrate according to claim 5, wherein the outermost resin insulating layer is a first solder resist layer.

7. The wiring substrate according to claim 1, further comprising:
an adhesive film formed between the second resin insulating layer and the electrode of the component, and
a via conductor formed to penetrate through the second resin insulating layer and the adhesive film such that the via conductor reaches the electrode of the component.

8. The wiring substrate according to claim 2, further comprising:
a second via conductor formed to penetrate through the third resin insulating layer and the lowermost first resin insulating layer.

9. The wiring substrate according to claim 1, further comprising:
an adhesive film formed between the second resin insulating layer and the electrode of the component such that the adhesive film fixes the component to the second resin insulating layer.

10. The wiring substrate according to claim 2, wherein the first resin insulating layer is formed such that the plurality of resin insulating layers is consisting of the uppermost first resin insulating layer and the lowermost first resin insulating layer.

11. The wiring substrate according to claim 8, wherein the second via conductor penetrates only the third resin insulating layer and the lowermost first resin insulating layer.

12. The wiring substrate according to claim 6, further comprising:
a second solder resist layer formed at a position farthest from the first solder resist layer; and
a fourth resin insulating layer comprising a reinforcing material and formed in contact with the second solder resist layer and on an inner side of the second solder resist layer,
wherein the first resin insulating layer, the second resin insulating layer, and the third resin insulating layer do not contain a reinforcing material.

13. The wiring substrate according to claim 12, wherein the first solder resist layer and the second solder resist layer do not contain a reinforcing material, and the fourth resin insulating layer has a thickness that is greater than a thickness of the first resin insulating layer.

14. The wiring substrate according to claim 4, further comprising:
a second solder resist layer formed at a position farthest from the first solder resist layer; and
a fourth resin insulating layer comprising a reinforcing material and formed in contact with the second solder resist layer and on an inner side of the second solder resist layer,
wherein the first resin insulating layer and the third resin insulating layer do not contain a reinforcing material.

15. The wiring substrate according to claim 1, wherein the second resin insulating layer has an alignment mark formed on a surface on an opposite side with respect to a surface facing the first surface of the first resin insulating layer.

16. The wiring substrate according to claim 2, wherein the second resin insulating layer is forming an outermost resin insulating layer.

17. The wiring substrate according to claim 16, wherein the outermost resin insulating layer is a first solder resist layer.

18. A method for manufacturing a wiring substrate, comprising:
forming a metal layer on a support plate;
forming a first alignment mark on the metal layer;
laminating a second resin insulating layer on the metal layer such that the second resin insulating layer covers the first alignment mark;
forming a first conductor layer on the second resin insulating layer;
forming an uppermost first resin insulating layer on the second resin insulating layer such that the uppermost first resin insulating layer covers the first conductor layer;
forming a second conductor layer on the uppermost first resin insulating layer;
forming a lowermost first resin insulating layer on the uppermost first resin insulating layer such that the lowermost first resin insulating layer covers the conductor layer;
forming a cavity in the uppermost first resin insulating layer and the lowermost first resin insulating layer such that the cavity penetrates through the uppermost first resin insulating layer and the lowermost first resin insulating layer;
accommodating a component in the cavity formed in the uppermost first resin insulating layer and the lowermost first resin insulating layer such that the component is positioned relative to the first alignment mark;
forming a third resin insulating layer on the lowermost first resin insulating layer;
forming a third conductor layer on the third resin insulating layer;
removing the support plate and the metal layer from the second resin insulating layer; and
forming an opening in the second resin insulating layer at a position relative to the first alignment mark such that the opening penetrates through the second resin insulating layer and exposes an electrode of the component.

19. The method for manufacturing a wiring substrate according to claim 18, further comprising:
forming an opening in the third resin insulating layer and the lowermost first resin insulating layer such that the opening penetrates through the third resin insulating layer and the lowermost first resin insulating layer and reaches the second conductor layer; and
forming a via conductor in the opening formed in the third resin insulating layer and the lowermost first resin insulating layer such that the via conductor connects the second conductor layer and the third conductor layer.

20. The method for manufacturing a wiring substrate according to claim 18, further comprising:
forming a second via conductor the opening formed in the second resin insulating layer such that the second via conductor fills the opening formed in the second resin insulating layer.
